(19) United States
(12) Patent Application Publication
(10) Pub. No.: US 2025/0248016 A1
(43) Pub. Date: Jul. 31, 2025

(54) UNIVERSAL FIXTURE DESIGN

(71) Applicant: Apple Inc., Cupertino, CA (US)

(72) Inventors: Aishwarya SHIVACHANDAR, Cupertino, CA (US); Lee Hau Tan, Shanghai (CN)

(73) Assignee: Apple Inc., Cupertino, CA (US)

(21) Appl. No.: 18/424,640

(22) Filed: Jan. 26, 2024

(51) Int. Cl. H05K 13/00; H05K 13/04

(52) U.S. Cl. CPC H05K 13/0069; H05K 13/046

(57) ABSTRACT

A universal fixture design reduces the financial and environment costs associated with printed circuit board (PCB) design by creating a fixture with universal pieces that may be reused not only in PCB design for various electronic devices, but also through design iterations of those devices over a product's life cycle. The present disclosure describes a structure having a base frame and a support structure. The support structure is attached and detached to the base frame to support a first substrate and a second substrate. The support structure may include openings that are arranged to allow electronic components to be placed on the first substrate. The support structure may also include a subset of the openings that are arranged to allow placement of a second set of electronic components on the second substrate.

### FIELD

This disclosure relates to a universal fixture design for printed circuit boards during surface mount technology industrial processes.

### BACKGROUND

Fixtures are used to support printed circuit boards (PCBs) for electronic devices during surface mounting industrial processes. Each PCB design can have an accompanying unique fixture design for use during surface mounting industrial procedures, manufacturing, and transportation of the PCB during these processes. Each fixture can have limited use for the specific PCB it was designed for. Additionally, when the PCB is redesigned, such as to accommodate new or advanced electronic components (e.g., surface mount devices or SMDs) or as a result of a redesign of the electronic device, the fixture is no longer usable during surface mounting industrial procedures. Therefore, a new fixture design is required each time the PCB is redesigned. As electronic devices continue to advance, they are frequently redesigned and this process has both significant financial and environment costs associated with redesigning the fixtures for each iteration of the PCB.

### SUMMARY

A universal fixture design reduces the financial and environment costs associated with PCB design by creating a fixture with universal pieces that may be reused not only in PCB design for various electronic devices, but also through design iterations of those devices over multiple product life cycles.

Embodiments of the present disclosure include a structure having a base frame and a support structure. The support structure is configured to be attached and detached to the base frame to support a first substrate and a second substrate. The support structure may include openings that are arranged to allow electronic components to be placed on the first substrate. The support structure may also include a subset of the openings that are arranged to allow placement of a second set of electronic components on the second substrate.

Embodiments of the present disclosure include a system having a support structure, a base frame, and a cover structure. The support structure is configured to be attached and detached to the base frame to support a first substrate and a second substrate. The support structure may include openings that are arranged to allow electronic components to be placed on the first substrate. The support structure may also include a subset of the openings that are arranged to allow placement of a second set of electronic components on the second substrate. The base frame may be configured to be attached and detached from the support structure. The cover structure may attach and detach from the base frame over the support structure and the first and second substrates to secure the support structure and the first and second substrates to the base frame.

Embodiments of the present disclosure include a method for positioning and placing a first substrate and a second substrate for surface mount assembly procedures. The method includes positioning the first substrate onto a support structure having a support plate with a first set of openings and a second set of openings. A first set of electronic components are placed onto the first substrate, where the first and second sets of openings support placement of the first electronic components. A second substrate is positioned onto the support structure, and a second set of electronic components is placed onto the second substrate, where a subset of the first and second sets of openings support placement of the second electronic components.

### BRIEF DESCRIPTION OF THE DRAWINGS

Aspects of the present disclosure are best understood from the following detailed description when read with the accompanying figures. It is noted that, according to the standard practice in the industry, various features are not drawn to scale. In fact, the dimensions of the various features may be arbitrarily increased or reduced for clarity of discussion.

FIG. 1 is an illustration of a block diagram for a surface mount assembly system, according to some embodiments.

FIG. 2 is an illustration of a base frame, according to some embodiments.

FIG. 3 is an illustration of a support structure, according to some embodiments.

FIG. 4 is an illustration of a cover structure, according to some embodiments.

FIG. 5A is an illustration of a transport structure, according to some embodiments.

FIG. 5B is an illustration of a protective insert for a transport structure, according to some embodiments.

FIG. 6 is an illustration of a method for positioning and placing substrates for surface mount assembly procedures, according to some embodiments.

FIG. 7 is an illustration of various exemplary systems or devices that can include the disclosed substrates.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. In addition, the present disclosure repeats reference numerals and/or letters in the various examples. This repetition is for the purpose of simplicity and clarity and, unless indicated otherwise, does not in itself dictate a relationship between the various embodiments and/or configurations discussed.

It is noted that references in the specification to “one embodiment,” “an embodiment,” “an example embodiment,” and “exemplary” indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

It is to be understood that the phraseology or terminology herein is for the purpose of description and not of limitation, such that the terminology or phraseology of the present specification is to be interpreted by those skilled in relevant art(s) in light of the teachings herein.

The following disclosure describes aspects of an assembly structure and transportation structure for use during surface mount assembly for printed circuit boards (PCBs). Specifically, the present disclosure describes an assembly structure with a base frame, a support structure, and a cover structure. The assembly structure is configured to support one or more substrates during surface mount assembly processes. Additionally, the present disclosure describes a transportation structure with a transportation tray and a protective insert for the one or more substrates once the surface mount assembly processes are complete. The one or more substrates may include PCBs, which undergo surface mount technology assembly to attach various electronic components (e.g., surface mount devices or SMDs) to the PCBs. Aspects of the assembly structure and transportation structure are universal, meaning the structures support each of the one or more PCBs of various sizes. Other assembly structures and transportation structures are designed for a specific PCB. The universal aspects of the assembly and transportation structures described herein allow for reuse and retrofitting of the assembly structure and the transportation structure. The universal design of the structures reduces the cost associated with assembly and manufacturing of the electronic devices corresponding to the PCBs. Additionally, reuse of the structures reduces the overall environmental footprint of manufacturing and assembly for the PCBs and corresponding devices by reducing the number of assembly and transportation structures required.

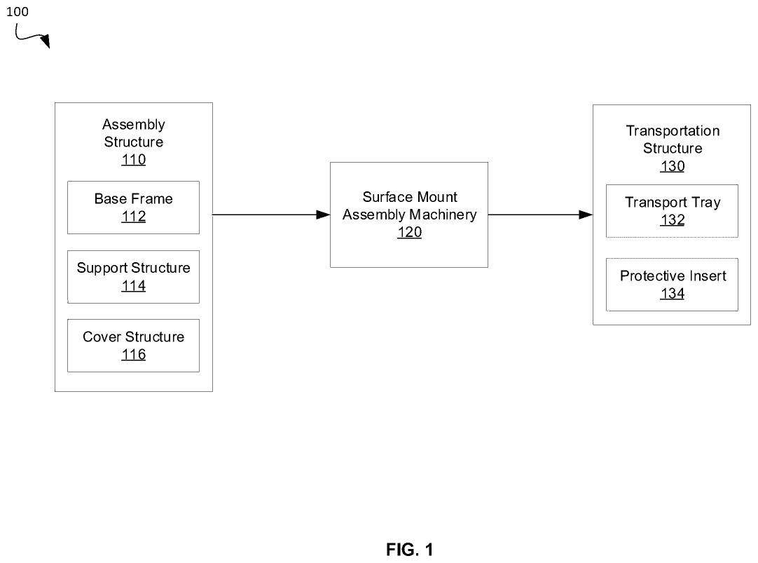

FIG. 1 is an illustration of a block diagram for a surface mount assembly system 100, according to some embodiments. Surface mount assembly system 100 includes an assembly structure 110, one or more surface mount assembly machinery 120, and a transportation structure 130. Assembly structure 110 includes a base frame 112, a support structure 114, and a cover structure 116. Base frame 112 is a universal fixture, designed to secure support structures of support structure 114 that support one or more substrates. Support structure 114 is configured to be removably disposed on base frame 112 and support the one or more substrates. In some embodiments, the substrate is a PCB. In some embodiments, support structure 114 has openings that allow a set of electronic components to be placed on the substrate during a surface mounting operation performed by surface mounting assembly machinery 120. Each of the one or more substrates may have a unique design and unique set of electronic components. A first subset of the openings may be used for a first substrate and a second subset of the openings may be used for a second substrate. In some embodiments, rather than individual substrates, multiple substrates may be attached to support structure 114.

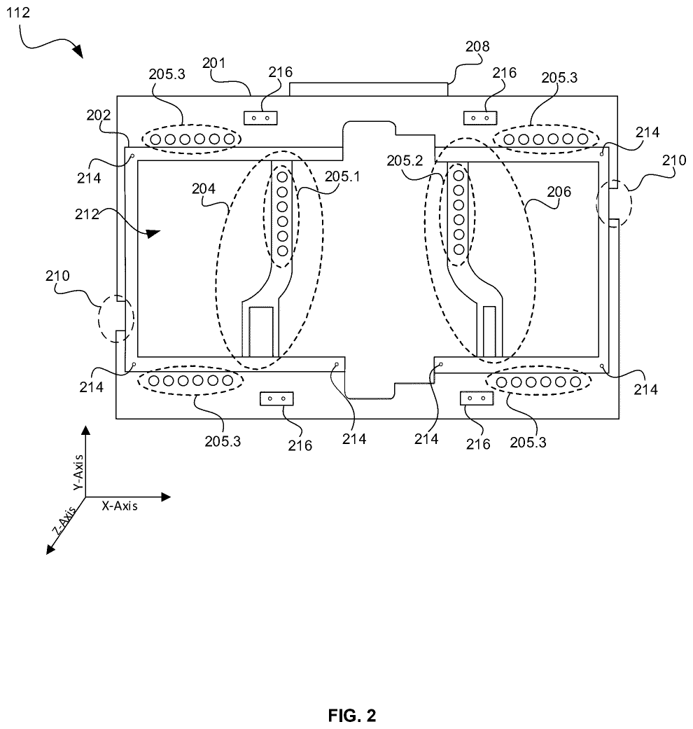

Once support plate 114 is secured to base frame 112 and the substrate is secured to support plate 114, cover structure 116 may be removably disposed on base frame 112 to secure the substrate onto to support plate 114. Cover structure 116 is attached over the substrate to also protect the substrate during operations performed by surface mount assembly machinery 120. Cover structure 116 may have a central opening to allow for placement of electronic components. Cover structure 116 may be a universal structure that can be used to secure and protect substrates. Each of base frame 112, support structure 114, and cover structure 116 are described in more detail in FIGS. 2-4, respectively. In some embodiments, cover structure 116 may have covered portions within the central opening over the first and/or second substrate that prevents (or blocks) placement of electronic components. These covered portions may coincide with the placement of other components within the electronic device that are adjacent or attached to the first substrate, but not an electronic component attached to the substrate during operations performed by surface mount assembly machinery 120.

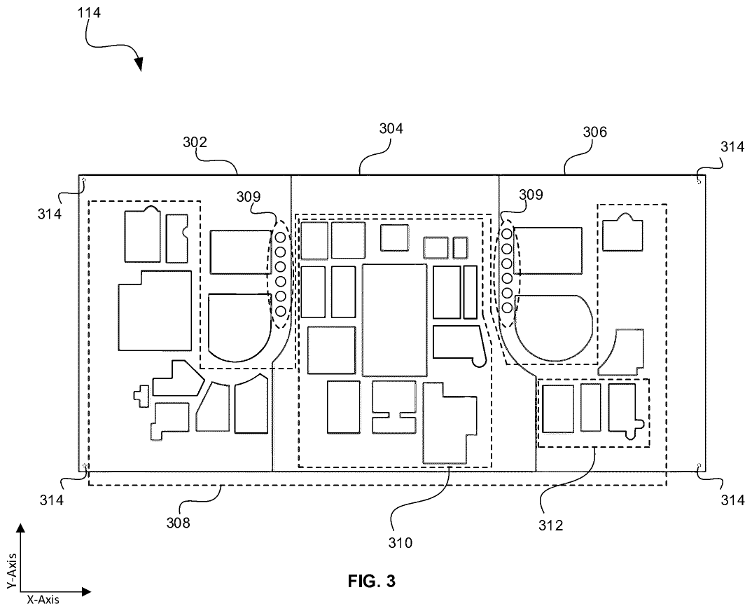

In some embodiments, the first substrate and the second substrate may be different sizes (e.g., different width and/or length dimensions) from one another and may have different electronic component layout configurations. Support structure 114 may include support plates to secure the substrates with different sizes and electronic component layout configurations, as described in FIG. 3 below. The support plates may allow the different first and second substrates to be secured to base frame 112 and secured by cover structure 116.

For example, if the first substrate is a PCB for a portable electronic device, the PCB may be redesigned as the corresponding electronic components mounted to the PCB are redesigned. The redesign may result in a substantially different shape and/or electronic component layout configuration compared to a previous design. In this case, support structure 114 may no longer be able to support the first substrate. For example, the openings on the support plates of support structure 114 may need to be redesigned to match the redesigned electronic component layout configuration of the first substrate. The support plates may be redesigned and configured to be removably disposed on base frame 112 and have openings arranged to support placement of electronic components onto the redesigned first substrate by surface mount assembly machinery 120. The reuse of base frame 112 and cover structure 116—after the redesign of support structure 114—may reduce the cost and environmental impact of the manufacturing and assembly of PCBs.

Referring to FIG. 1, in some embodiments, surface mount assembly machinery 120 may include machinery performing different operations, such as a solder paste dispense operation, a pick and place operation, and a reflow operation. The surface mount assembly process attaches specific electronic components, known as surface mount devices (SMDs), to PCBs. In some embodiments, the first and/or the second substrate is attached to support structure 114, which is secured on base frame 112 throughout the surface mount assembly process. After the solder paste dispense process is completed, cover structure 116 is coupled to the base frame such that the first and/or second substrate is secured to support structure 114 between base frame 112 and cover structure 116. The surface mount assembly process can be an automated process to produce a high number of PCBs for various electronic devices, such as portable electronic devices (e.g., personal computing devices, mobile phones, and desktop computing devices). Computer automated design (CAD) drawing data or Gerber data may be used to determine an order of placement for the electronic components. The data files include specifications for each electronic component and their corresponding placement on the PCB.

As part of surface mount assembly machinery 120, a solder paste machine may apply solder paste to the PCB to the pads, or electrical connection points, for the electronic components that will be placed on the PCB. The application of solder paste may done through stenciling or jet printing. After the solder paste has been applied to the PCB, the electronic components may be placed onto the PCB using a pick and place machine. The pick and place machine may pick each electronic component from packaging using vacuum suction and place the electronic component at the appropriate location on the PCB. For example, electronic components may be individually placed in openings 308—as described below with respect to FIG. 3—in accordance with the arrangement of the first substrate and/or the second substrate.

In some embodiments, a reflow soldering machine is used to solder the electronic components onto the PCB using the solder paste previously applied by the solder paste machine. During the reflow process, the electrical connections between components on the PCB are formed. This may be a highly automated process based on continuously producing the same or similar PCBs, in which efficiency may be a key factor. Redesigning the PCBs for electronic devices can have a significant effect on the efficiency, cost, and environment impact of this process. The universal design of base frame 112 and cover structure 116 allow this redesign process to be more efficient because the same base parts may be used despite the size and/or electronic component layout configuration of the PCB.

Referring to FIG. 1, after the surface mount assembly operations have been performed on the PCB while secured using assembly structure 110, the PCB is removed from surface mount assembly machinery 120 and placed in transportation structure 130.

Transportation structure 130 includes a transport tray 132 and a protective insert 134. In some embodiments, transport tray 132 is a universal tray that may hold PCBs with different sizes. Protective insert 134 may be an insert contoured for each PCB, which allows PCBs of different sizes to be securely placed in transport tray 132. Transport tray 132 and protective insert 134 may be reused repeatedly after the surface mount assembly process has been completed, according to some embodiments.

As described above, redesigning the PCBs for electronic devices can have a significant effect on the efficiency, cost, and environment impact of this process. The universal design of transport tray 132 allows this redesign process to be more efficient because the same base tray may be used despite the size and/or electronic component layout configuration of the PCB. In combination with the use of base frame 112, support structure 114, and cover structure 116, these versatile fixtures and trays may contribute significantly to the reduction of the environment and monetary manufacturing costs of redesigning electronic devices.

FIG. 2 is an illustration of base frame 112, according to some embodiments. Base frame 112 includes a first frame structure 202, a second frame structure 204, and a third frame structure 206, according to some embodiments. Frame structures 202, 204, and 206 may be disposed in a central opening 212 configured to support a support structure. Base frame 112 may be rectangular in shape and include a protrusion 208 and/or indication 210 on the outer most edge of base frame 112 to accommodate use in machinery for the surface mount technology assembly processes, such as pick and place, printing, and solder reflow. Additionally, the shape of central opening 212 may depend on the requirements for the machinery and one or more substrates secured by support structure 114. For example, central opening 212 may be large enough to accommodate one or more support structures 114 depending on a size of the substrate secured to support structure 114. In some embodiments, first frame structure 202 forms central opening 212. First frame structure 202 may have a smaller depth than base frame 112 to allow support structure 114 to rest flush with the top surface of base frame 112. For example, first frame structure 202 may extend a short distance along the z-axis, as shown in FIG. 2, beneath a top surface first frame structure 112.

In some embodiments, second frame structure 204 and third frame structure 206 may provide additional support to secure support structure 114. For example, second frame structure 204 and third frame structure 206 may connect portions of first frame structure 202 through central opening 212 to provide additional support for support structure 114. In some embodiments, first frame structure 202, second frame structure 204, and third frame structure 206 may have one or more attachments points to allow support structure 114 to securely attach to base frame 112. Base frame 112 and support structure 114 may include alignment pins 214 and corresponding alignment holes 314 on support structure 114 that allow alignment fasteners, such as alignment pins or magnets, to be placed in the alignment holes on support structure 114. Base frame 112 may include multiple alignment pins 214 that protrude from the surface of base frame 112 on first, second, and third frame structures 202, 204, and/or 206. Alignment pins 214 have corresponding alignment holes 314 on support structure 114. When coupled, alignment pins 214 may be inserted in alignment holes 314 of support structure 114, as further described in FIG. 3.

The alignment pins 214 on base frame 112 and alignment holes 314 on support structure 114 may correspond to one another. Support structure 114 alignment holes 314 may be holes that allow a fastener to be placed in them when they are aligned, securely coupling base frame 112 to support structure 114. Support structure 114 may be placed on base frame 112 so that the alignment holes 314 may be moved coincident and the alignment pins 214 may be inserted. In some embodiments, support structure alignment holes 314 may be through holes in that they extend completely through support structure 114. In some embodiments, alignment pins 214 may be pins placed in second frame structure 204 and third frame structure 206 that align with corresponding alignment openings in support structure 114, support structure alignment holes 314 (of FIG. 3). Fasteners, such as alignment pins 214 on base frame 112, may fit in alignment holes 314 and allow support structure 114 to securely fasten to second frame structure 204 and third frame structure 206, according to some embodiments. In some embodiments, the fasteners may be alignment pins or fasteners intended to removably dispose the two structures.

Base frame 112 may also have heat dissipation openings 205 configured to allow heat to dissipate during surface mount assembly processes, according to some embodiments. Heat dissipation openings 205.1-205.3 may be placed at various locations on base frame 112, including first, second, and third frame structures. For example, heat dissipation openings 205.1 are placed on first frame structure 205.1 and may help dissipate heat associated with surface mount assembly procedures performs on the first and/or second substrate coupled to support structure 114. Heat dissipation openings 205.2 and 205.3 function similarly at different locations on base frame 112. Additionally, in some embodiments heat dissipation openings 205.1-205.3 may be grouped, as shown in FIG. 2, scattered individually on base frame 112, or a combination of both. Modeling of the first and second substrate during the design process may indicate the best location(s) for heat dissipation openings 205.1-205.3. Heat dissipation openings 205.1-205.3 may also be retroactively added to base frame 112 if a redesign of the electronic device or the first and/or second substrate require additional heat dissipation openings.

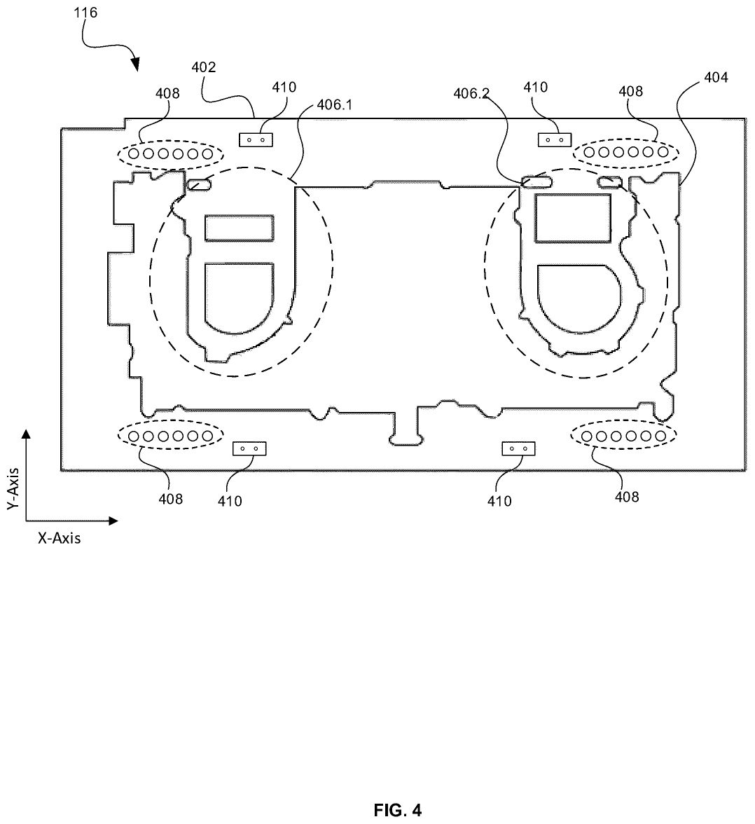

Similar to attachment pins 214 previously described, cover attachment 216 may be located between outer edge 201 of first frame structure 202 of base frame 112. Cover attachment 216 may be an insert in base frame 112 that contains one or more magnetic fasteners that allow magnets to be placed on base frame 112 that allow base frame 112 and cover structure 116 to attach to one another. Cover structure 116 may have mirroring inserts as base attachment points 410 (of FIG. 4). The corresponding inserts may allow cover structure 116 to be attached to base frame 112 over support structure 114 and the first and/or second substrate after the placement of electronic components using surface mount assembly machinery 120.

FIG. 3 is an illustration of support structure 114 configured to support a first substrate and a second substrate, according to some embodiments. Support structure 114 may include support plates (e.g., a first support plate 302, a second support plate 304, and a third support plate 306) configured to be removably disposed on base frame 112 and to support a substrate and openings 308 arranged to allow placement of electronic components on the substrate.

In some embodiments, support structure 114 may include first support plate 302, second support plate 304, and third support plate 306, where each of the support plates may support the first substrate and/or the second substrate. For example, first support plate 302 and third support plate 306 may be removably disposed on base frame 112 to support the first substrate. In some embodiments, a fourth support plate may be exchanged for second support plate 304 for the first substrate. Additionally, first support plate 302 and third support plate 306 may also be removably disposed on base frame 112 in addition to second support plate 304 to support the second substrate. The first substrate and the second substrate may have a common type of electronic components (e.g., a processor, a memory device, and other suitable types of devices) and/or features that allow first support plate 302 and third support plate 306 to be commonly used, according to some embodiments.

For example, the first substrate may be a PCB for a first model of an electronic device (e.g., desktop computer, laptop, and mobile computing device) and the second substrate may be a PCB for a different model of the electronic device, where the second substrate is smaller (e.g., in width dimensions in the y-axis and/or length dimensions in the x-axis) than the first substrate. The common features of the first substrate and the second substrate may allow first support plate 302 and third support plate 306 to support both the first substrate and the second substrate. Second support plate 304 may be interchangeable with the fourth support plate when the first substrate is being secured to support structure 114. The footprint of second support plate 304 and the fourth support plate is such that interchanging the two plates allows support structure 114 to remain a continuous surface to secure the substrates, while changing the positions and shapes of the openings. The openings of the fourth support plate are arranged to allow placement of electronic components specific to the first substrate and meet the heat dissipation requirements for the first substrate. For example, the first substrate may have a first subset of electronic components that are placed only on the first substrate. In this case, the fourth support plate may have unique openings that allow the subset of electronic components specific to the first substrate to be placed on the first substrate. Similarly, second support plate 304 may have openings unique to the second subset of electronic components and the second substrate. When only the first substrate is being used in the surface mount assembly system, the fourth support plate may be used in place of second support plate 304 and secured to base frame 112. Both second support plate 304 and the fourth support plate may have the same dimensions so they can be exchanged depending on the substrate, but the subset of multiple openings may be different.

In some embodiments, the common type of electronic components may be located to allow second support plate 304 to be commonly used to support the first substrate and the second substrate. For example, the layout of electronic components and use of electronic components on the first substrate and the second substrate may not be completely unique. In this case, second support plate 304 may have openings that are used to place the common electronic components on both the first substrate and the second substrate. The common use of the support plates depends on the common layout and common electronic components of the first substrate and the second substrate, according to some embodiments.

In some embodiments, openings 308 are arranged across support structure 114 on first support plate 302, second support plate 304, and third support plate 306. Second support plate 304 has a subset of openings 308 (also referred to herein as “openings 310”) arranged for placement of electronic components specific to the second substrate. Additionally, a subset of these openings may be used to meet the heat dissipation requirements for the substrate and may not have components placed in the opening. In some embodiments, second support plate 304 may not be used placement of electronic components by surface mount assembly machinery 120 for the first substrate. Thus, openings 310 may not be used for the first substrate. In some embodiments, a subset of openings 308 on first support plate 302 and third support plate 306 is common between the first substrate and the second substrate. The electronic components and placement of the electronic components corresponding to the subset of openings 308 on first support plate 302 and third support plate 306 may be the same for the first substrate and the second substrate, according to some embodiments.

In some embodiments, first support plate 302 and/or third support plate 306 may have an over lapping subset of openings 308 that are arranged for placement of electronic components, as described above. Additionally, a subset of these openings may be used to meet the heat dissipation requirements for the substrates and may not have components placed in the opening. Some of the openings may be specific to either the first or second substrates. In some embodiments, first support plate 302 and/or third support plate 306 may have a different subset of openings 308 that are arranged for placement of electronic components only on the first substrate or the second substrate. For example, a subset of openings 308 in third support plate 306 (also referred to herein as “openings 312”) are arranged for placement of electronic components on the first substrate. Openings 312 may not be used for placement of electronic components by surface mount assembly machinery 120 for the second substrate. To place the subset of electronic components of for the second substrate, another support plate may be exchanged for third support plate 306.

Referring to FIG. 3, in some embodiments, support structure 114 may have a support plate design to allow the first substrate and the second substrate to be secured to support structure 114 at the same time. The first substrate and the second substrate may be secured on different portions of support structure 114, and the corresponding support plates, that have openings for the subset of electronic components and common electronic components. For example, the first substrate may be placed on support structure 114 adjacent to the second substrate along the y-axis. The upper portions of support plate 114 and the openings in that portion may mirror the layout of electronic components on the first substrate. The lower portions of support plate 114 and the openings in that portion may mirror the layout of electronic components on the second substrate. In some embodiments, the first and second substrates may separate support structure 114 vertically, horizontally, and/or diagonally within the x-y plane, with reference to FIG. 3. If the first and second substrate both fit on support structure 114, support plates may be designed to fit the configuration of the layout of the one or more substrates while keeping the footprint of support structure 114 consistent so that it may be secured to base frame 112.

FIG. 4 is an illustration of cover structure 116, according to some embodiments. Cover structure 116 includes a cover frame 402, a central opening 404, and a protrusion 406, according to some embodiments. In some embodiments, cover structure 116 may be attached to base frame 112 over support structure 114 and the first and/or the second substrate. Cover frame 402 may have one or more alignment openings to allow cover structure 116 to removably attach to base frame 112, according to some embodiments. For example, the cover structure 116 heat dissipation openings 408 may be holes placed between cover frame 402 and central opening 404 to allow heat to dissipate during surface mount assembly procedures. Magnets may be used as fasteners in base attachment points 410 to allow cover structure 116 to be attached to base frame 112 once the solder paste dispensing operation has been completed. Cover structure 116 may be reused each time a new substrate and support structure 114 configuration are secured on base frame 112.

Central opening 404 of cover structure 116 may allow electronic components to be place on the first and/or second substrate supported by support structure 114, according to some embodiments. Central opening 404 may align with central opening 212 of base frame 112, while leaving the openings of support structure 114 arranged to allow placement of electronic components on the first and/or second substrate open to access by surface mount assembly machinery 120. In some embodiments, central opening 404 may have an uneven edge indicating the outer edges of openings 308 of support structure 114.

In some embodiments, central opening 404 may also include a protrusion 406. Protrusion 406 may indicate areas of the first or second substrate where electronic components will not be placed by surface mount assembly machinery 120. Instead, other electronic components not subject to surface mount assembly may be located in the electronic device near the first or second substrate in those locations. For example, a fan may be used for cooling in the electronic device, but it is not placed on the first or second substrate and therefore not subject to surface mount assembly. Other components may also be placed around the first or second substrate in the electronic device and influence the shape of the first or second substrate. The first and second substrates may be irregularly shaped to accommodate the other components in the first or second substrates. In place of the fan or other component, a supporting panel may be used to create a continuous surface for the substrate to be secured. Protrusions 406.1 and 406.2 take on the shape of the fan(s), or other component, used in the electronic device and the supporting panel fits the shape of the empty space of protrusions 406.1 and 406.2. The supporting panel prevents access to these areas by surface mount assembly machinery 120 and allows the first and second substrates to be properly aligned during surface mount assembly procedures.

Additionally, cover structure 116, including protrusions 406.1 and 406.2, may be retrofitted to accommodate a new substrate layout and new support plates of support structure 114. If the layout or dimensions of the first and second substrates are redesigned and therefore support plates of support structure 114 may be redesigned so components may be placed on the first and second substrate in areas covered by protrusions 406.1 and 406.2, the protrusions may be removed from cover structure 116 individually or together to allow access to these areas for surface mount assembly machinery 120.

In some embodiments, central opening 404 does not include protrusions 406.1 and 406.2 in the design of cover structure 116. Put differently, the design of cover structure 116 does not include protrusions 406.1 and 406.2 such that the protrusions can be later removed to accommodate a new substrate layout and new support plates of support structure 114.

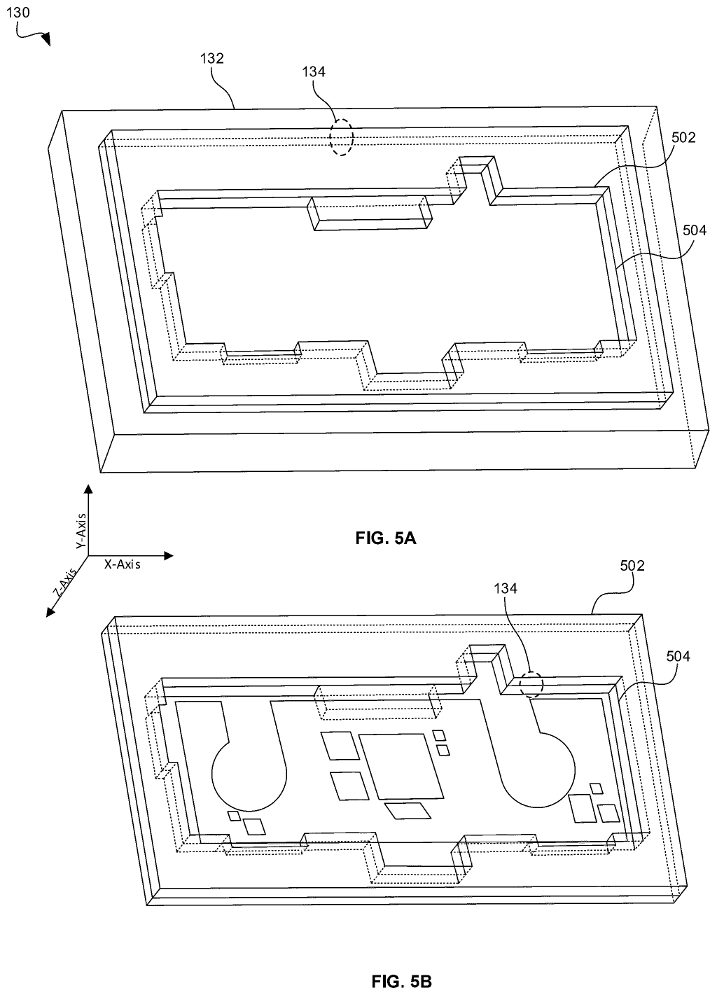

FIG. 5A is an illustration of transportation structure 130, according to some embodiments. FIG. 5A includes transportation structure 130, transport tray 132, and protective insert 134, according to some embodiments. In some embodiments, protective insert 134 includes a first layer 502, a second layer 504, or a combination of the two layers in a single layer. Transport tray 132 may hold protective insert 134, which holds the first substrate or the second substrate. Outer edges of protective insert 134 may align with a cavity of transport tray 132 so that protective insert 134 will not move during transportation of the first substrate or the second substrate. In some embodiments, protective insert 134 may have a protrusion that corresponds to indentations in transport tray 132 to ensure a secure fit. For example, transport tray 132 may have rounded inner corners and protective insert 134 may have rounded corners that sit flush with the round corners of transport tray 132. Additionally, transport tray 132 may have indentations that are rectangular or trapezoidal in shape, and protective insert 134 may have protrusions in the corresponding shape. In some embodiments, transport tray 132 and protective insert 134 may be made out of a non-conductive, electrostatic discharge (ESD) safe, material. Additionally, protective insert 134 may be made out of a compressive, non-conductive material to protect the electronic components of the first substrate or the second substrate that may be sensitive to electrostatic discharge.

FIG. 5B is an illustration of protective insert 134, according to some embodiments. Protective insert 134 includes first layer 502 and second layer 504. Protective insert 134 may be contoured to fit the first substrate or the second substrate. For example, protective insert 134 may have an opening that the first substrate or the second substrate may be placed in for transportation. Second layer 504 may have protrusions that the first substrate or the second substrate may be placed on to prevent the substrate from resting on the bottom of transport tray 132. First layer 504 may be placed on top of second layer 502. In some embodiments, the first substrate or the second substrate may be placed between first layer 502 and second layer 504 when protective insert 134 and the substrate are placed in transport tray 132.

Protective insert 134 may be customized to fit the different sizes of the first substrate or the second substrate, according to some embodiments. For example, the first substrate may have a first length in the direction of the x-axis and a first width in the direction of the y-axis and the second substrate may have a second length and a second width. The first length in the direction of the x-axis and width in the direction of the y-axis associated with the first substrate may be different than the second length and width associated with the second substrate—e.g., the first substrate may have larger length and width dimensions than that of the second substrate. The opening of protective insert 134 may be different for the first substrate and the second substrate to accommodate different dimensions of the substrates. The length and width dimensions of protective insert 134 may remain the same for the first substrate and the second substrate so that transport tray 132 may be uniform and used for the first substrate and the second substrate, according to some embodiments. Protective insert 134 may be used for either the first substrate or the second substrate. In some embodiments, both transport tray 132 and protective insert 134 may be reused after transport of the first or second substrate is complete and the substrate is removed. Further, both transport tray 132 and protective insert 134 may be reused for the next generation of the electronic device and/or similar designs.

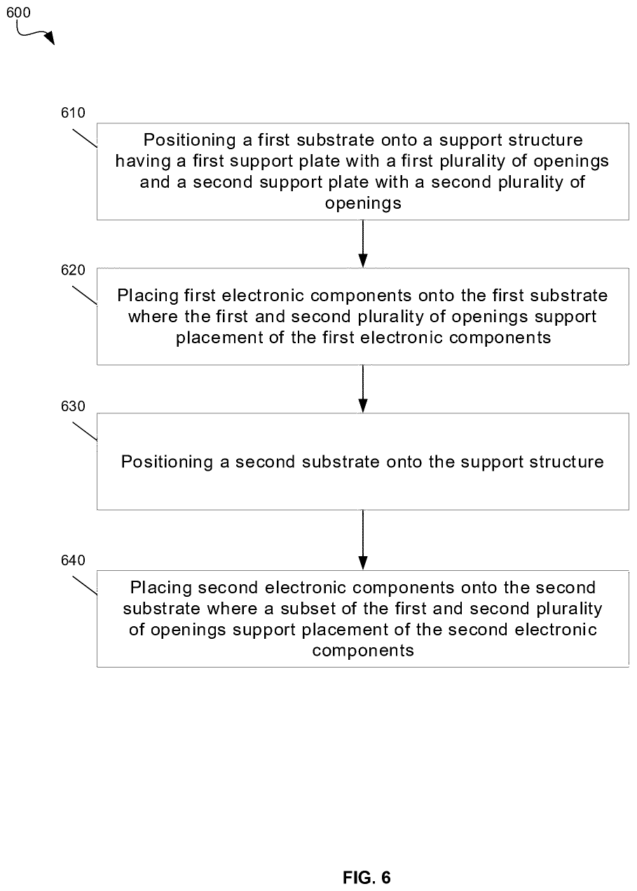

FIG. 6 is an illustration of a method 600 for positioning and placing substrates for surface mount assembly procedures, according to some embodiments. For illustrative purposes, the operations illustrated in method 600 will be described with reference to FIGS. 1-4, 5A, and 5B and assembly structure 110 and transport structure 130. Other representations of assembly structure 110 and transport structure 130 are within the scope of the present disclosure. Also, additional operations may be performed between various operations of method 600 and may be omitted merely for clarity and ease of description. The additional operations can be provided before, during, and/or after method 600, in which one or more of these additional operations are briefly described herein. Additionally, some of the operations may be performed simultaneously or in a different order than shown in FIG. 6. In some embodiments, one or more other operations may be performed in addition to or in place of the presently-described operations.

At operation 610 of FIG. 6, a first substrate is positioned onto a support structure having a first support plate with a first set of openings and a second support plate with a second set of openings. Referring to FIG. 3, the first substrate is positioned onto support structure 114, which includes first support plate 302, second support plate 304, and third support plate 306. First support plate 302 includes the first set of openings, which is a subset of openings 308. Third support plate 306 includes a second set of openings, which is a subset of openings 308.

At operation 620 of FIG. 6, first electronic components are placed on the first substrate at the location of the first and second sets of openings that support placement of the first electronic components. Referring to FIGS. 1 and 3, surface mount assembly machinery 120 places the first electronic components on the first substrate in the location of the subset of openings 308 that are applicable to the first substrate. The first electronic components may be attached and placed using solder paste, pick and place, and/or solder reflow machines as described with reference to FIG. 1 and/or follow industry PCB assembly practices.

At operation 630 of FIG. 6, a second substrate is positioned onto the support structure. Referring to FIG. 3, the second substrate is positioned onto support structure 114, along with the first substrate, which includes first support plate 302, second support plate 304, and third support plate 306. First support plate 302 has the first set of openings, which is a subset of openings 308. Second support plate 304 may have a subset of openings 308 that are arranged for placement of the second electronic components. Third support plate 306 may have openings 310 that may be used for the placement of the second electronic components on the second substrate. In some embodiments, operations 610 and 630 may be performed together by surface mounting assembly machinery 120.

At operation 640 of FIG. 6, second electronic components are placed onto the second substrate, where a subset of the first and second sets openings support placement of the second electronic components. Referring to FIGS. 1 and 3, surface mount assembly machinery 120 places the first electronic components on the first substrate in the location of the subset of openings 308 that are applicable to the second substrate, such as openings 310. The second electronic components may be attached and placed using solder paste, pick and place, and/or solder reflow machines as described with reference to FIG. 1 and/or follow industry PCB assembly. In some embodiments, a subset of openings of the first set of openings and the second set of openings may be used for heat dissipation in assembly structure 110 during surface mount assembly procedures and may not be used for placement of electronic components. In some embodiments, operations 620 and 640 may be performed together by surface mounting assembly machinery 120.

In some embodiments, before the first and second substrates and corresponding first and second electronic components are placed, support structure 114 including the support plates corresponding to the first and the second substrate may be secured to base frame 112. Base frame 112 and support structure 114 may include alignment openings that allow alignment fasteners, such as alignment pins or magnets, to be placed in the alignment openings. Support structure 114 is configured to be secured to base frame 112 when the alignment pins are inserted into the alignment openings on base frame 112 and support structure 114. The alignment openings on base frame 112 and support structure 114 may correspond so they may be moved coincident, or so the alignment openings are placed directly on top of each other, and the alignment pins may be inserted. For example, support structure alignment openings 309 may be aligned so they are directly on top of first base frame alignment openings 205. Alignment pins may then be placed through support structure alignment openings 309 and into first base frame alignment openings 205. Depending on the support plates used for the substrate being placed on support structure 114, base frame 112 may have a subset of the openings that correspond to different support plates. For example, first support plate 302 and second support plate 304 may have openings that correspond to different alignment openings on base frame 112.

In some embodiments, after the first and second substrates and corresponding first and second electronic components are placed, the first and second substrates may be removed from assembly structure 110 and placed in transport structure 130. Referring to FIGS. 5A and 5B, the first substrate may be placed on second layer 504 of protective insert 134. First layer 502 may be placed on top of second layer 504 and the first substrate. Protective insert 134 and the first substrate may be placed in transport tray 132. In some embodiments, protective insert 134 may have a specific opening design for the first substrate—e.g., specific length and width dimensions for the first substrate.

After the second substrate is removed from assembly structure 110, the second substrate may be placed on second layer 502, which is customized for the length and width dimensions of the second substrate. First layer 504 may be placed on top of second layer 504 and the second substrate. First layer 502 may also be customized for the length and width dimensions of the second substrate, according to some embodiments. Protective insert 134 may be placed in transport tray 132. Transport tray 132 has a uniform design that may hold protective insert 132 and the first substrate or the second substrate.

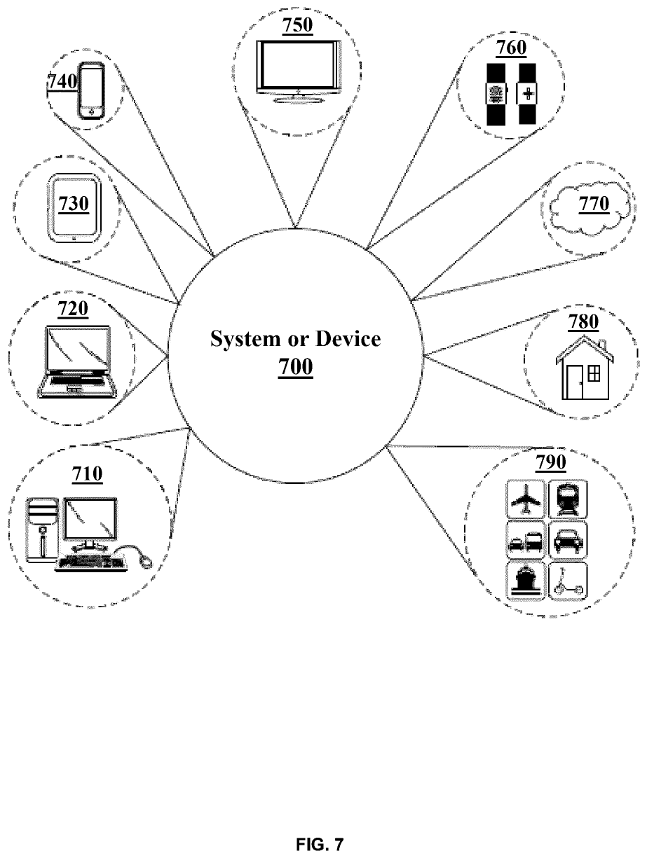

FIG. 7 is an illustration of exemplary systems or devices that can may represent the electronic devices of the first substrate and/or the second substrate included in the disclosed embodiments. System or device 700 can incorporate one or more of the disclosed embodiments in a wide range of areas. For example, system or device 700 can be implemented in one or more of a desktop computer 710, a laptop computer 720, a tablet computer 730, a cellular or mobile phone 740, and a television 750 (or a set-top box in communication with a television).

Also, system or device 700 can be implemented in a wearable device 760, such as a smartwatch or a health-monitoring device. In some embodiments, the smartwatch can have different functions, such as access to email, cellular service, and calendar functions. Wearable device 760 can also perform health-monitoring functions, such as monitoring a user's vital signs and performing epidemiological functions (e.g., contact tracing and providing communication to an emergency medical service). Wearable device 760 can be worn on a user's neck, implantable in user's body, glasses or a helmet designed to provide computer-generated reality experiences (e.g., augmented and/or virtual reality), any other suitable wearable device, and combinations thereof.

Further, system or device 700 can be implemented in a server computer system, such as a dedicated server or on shared hardware that implements a cloud-based service 770. System or device 700 can be implemented in other electronic devices, such as a home electronic device 780 that includes a refrigerator, a thermostat, a security camera, and other suitable home electronic devices. The interconnection of such devices can be referred to as the “Internet of Things” (IoT). System or device 700 can also be implemented in various modes of transportation 1190, such as part of a vehicle's control system, guidance system, and/or entertainment system.

The systems and devices illustrated in FIG. 7 are merely examples and are not intended to limit future applications of the disclosed embodiments. Other example systems and devices that can implement the disclosed embodiments include portable gaming devices, music players, data storage devices, and unmanned aerial vehicles.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a base frame; and
a support structure configured to be removably disposed onto the base frame and to support a first substrate and a second substrate, wherein the support structure comprises a plurality of openings arranged to support a placement of first electronic components onto the first substrate, and wherein a subset of the plurality of openings are arranged to support a placement of second electronic components onto the second substrate.

2. The structure of claim 1, wherein the base frame comprises a plurality of frame structures disposed in a central opening of the base frame and configured to secure the support structure within the base frame.

3. The structure of claim 1, wherein the first electronic components and the second electronic components comprise a common type of electronic component among the first and second electronic components, and wherein at least one of the subset of the plurality of openings is arranged to support a placement of the common type of electronic component onto the first and second substrates.

4. The structure of claim 1, wherein the support structure comprises a plurality of support plates configured to be removably disposed onto the base frame and to support the first and second substrates.

5. The structure of claim 4, wherein the plurality of support plates comprise a first support plate with a first set of openings of the plurality of openings and a second support plate with a second set of openings of the plurality of openings.

6. The structure of claim 5, wherein the first electronic components and the second electronic components comprise a common type of electronic component among the first and second electronic components, and wherein at least one of the first set of openings in the first support plate is arranged to support a placement of the common type of electronic component onto the first and second substrates.

7. The structure of claim 1, wherein the first substrate comprises a first length dimension and a first width dimension, wherein the second substrate comprises a second length dimension and a second width dimension, and wherein the first length and first width dimensions are larger than second length and second width dimensions, respectively.

8. A system, comprising:
a support structure configured to support a first substrate and a second substrate and comprising a first support plate with a first plurality of openings and a second support plate with a second plurality of openings, wherein the first and second plurality of openings are arranged to support a placement of first electronic components onto the first substrate, and wherein a subset of the first and second plurality of openings are arranged to support a placement of second electronic components onto the second substrate;
a base frame configured to removably couple to the support structure; and
a cover structure configured to attach to the base frame and to secure the support structure within the base frame.

9. The system of claim 8, further comprising:
a protective insert with an opening contoured to a shape of the first substrate or to a shape of the second substrate, wherein the protective insert is configured to support the first substrate with the first electronic components placed thereon or the second substrate with the second electronic components placed thereon; and
a transport tray configured to hold the protective insert.

10. The system of claim 9, wherein the protective insert comprises a compressible, non-conductive material.

11. The system of claim 8, wherein the first electronic components and the second electronic components comprise a common type of electronic component among the first and second electronic components, and wherein at least one of the first plurality of openings is arranged to support a placement of the common type of electronic component onto the first and second substrate.

12. The system of claim 8, wherein the first substrate comprises a first length dimension and a first width dimension, wherein the second substrate comprises a second length dimension and a second width dimension, and wherein the first length and first width dimensions are larger than second length and second width dimensions, respectively.

13. The system of claim 8, wherein the support structure comprises a plurality of alignment openings, and wherein the base frame comprises a plurality of alignment pins configured to be inserted into the plurality of alignment openings to position the support structure thereon.

14. The system of claim 8, wherein the base frame comprises a plurality of frame structures disposed in a central opening of the base frame and configured to secure the support structure within the base frame.

15. The system of claim 8, wherein the base frame comprises a plurality of locking mechanisms configured to secure the support structure thereon.

16. The system of claim 8, wherein the cover structure comprises one or more detachable portions to accommodate the placement of the first electronic components onto the first substrate or the placement of the second electronic components onto the second substrate.

17. A method, comprising:
positioning a first substrate onto a support structure having a first support plate with a first plurality of openings and a second support plate with a second plurality of openings;
placing first electronic components onto the first substrate, wherein the first and second plurality of openings support placement of the first electronic components;
positioning a second substrate onto the support structure; and
placing second electronic components onto the second substrate, wherein a subset of the first and second plurality of openings support placement of the second electronic components.

18. The method of claim 17, further comprising:
attaching a cover structure onto the base frame to secure the support structure within the base frame.

19. The method of claim 18, wherein attaching the cover structure comprises detaching one or more portions of the cover structure to accommodate the placement of the first electronic components onto the first substrate or the placement of the second electronic components onto the second substrate.

20. The method of claim 17, further comprising:
securing the first substrate with first electronic components placed thereon in a first protective insert, wherein the first protective insert comprises a first opening contoured to a shape of the first substrate;
placing the first protective insert having the secured first substrate in a transport tray;
securing the second substrate with second electronic components placed thereon in a second protective insert, wherein the second protective insert comprises a second opening contoured to the shape of the second substrate, wherein one or more dimensions of the second substrate are different from that of the first substrate, and wherein a shape and a perimeter of the first and second protective inserts are substantially the same; and
placing the second protective insert having the secured second substrate in the transport tray.
